(19) United States
(12) Patent Application Publication
(10) Pub. No.: US 2012/0253717 A1
(43) Pub. Date: Oct. 4, 2012

(54) BATTERY VOLTAGE DETECTOR AND BATTERY VOLTAGE DETECTING METHOD

(75) Inventors: Tsukasa ITO, Utsunomiya-shi (JP); Makoto YAMAUCHI, Yokohama-shi (JP)

(73) Assignee: KEIHIN CORPORATION, Tokyo (JP)

(21) Appl. No.: 13/431,191

(22) Filed: Mar. 27, 2012

(30) Foreign Application Priority Data
Mar. 30, 2011 (JP) 2011-074487

(51) Int. Cl. G01R 31/36

(52) U.S. Cl. 702/63

(57) ABSTRACT

A battery voltage detector includes: a voltage detection circuit; a voltage processor; and a power voltage. The voltage detection circuit is configured to detect a cell voltage of a battery cell. The voltage processor is configured to perform analog-to-digital conversion on the cell voltage with a predetermined period to collect cell voltage detection data. The power voltage monitoring circuit is configured to determine whether or not an instantaneous variation of an externally-supplied power voltage occurs, and output an instantaneous variation detection signal indicating a result of detection to the voltage processor. If the voltage processor detects based on the instantaneous variation detection signal that the instantaneous variation of the externally-supplied power voltage occurs, the voltage processor is configured to delete the cell voltage detection data that is the newest.

### BACKGROUND OF THE INVENTION

1. Field of the Invention

The present invention relates to a battery voltage detector and a battery voltage detecting method.

Priority is claimed on Japanese Patent Application No. 2011-074487, filed Mar. 30, 2011, the content of which is incorporated herein by reference.

2. Description of the Related Art

As known, a vehicle, such as an electric car or a hybrid car, is provided with a motor, and a high-voltage and high-capacity battery that supplies power to the motor. The motor driving battery includes multiple battery cells connected in series. The battery cell includes a lithium-ion battery, a nickel-metal hydride battery, or the like.

To monitor an overcharged state or an overdischarged state, technique of related art for detecting a cell voltage of each battery cell using a flying-capacitor-type voltage detection circuit has been known (see, for example, Japanese Patent Laid-Open Publication No. 2004-85208). An output voltage of the voltage detection circuit (voltage between terminals of a flying capacitor) is amplified by a differential amplifier, and then is converted by an A/D (analog to digital) convertor into digital data (cell voltage detection data).

In the related art, a high DC voltage output from the motor driving battery is converted by a voltage convertor into a low DC voltage, and thereby is used as a power voltage of an electric component required for detecting a cell voltage, such as an A/D convertor (the A/D convertor is included in a microcomputer in some cases). If the power voltage varies instantaneously during A/D conversion of the cell voltage, precise cell voltage detection data cannot be obtained.

For this reason, in the related art, an instantaneous variation of the power voltage is monitored by a software process by a microcomputer based on digital data of the power voltage which is obtained using the A/D convertor. Then, the cell voltage detection data obtained when an instantaneous variation occurs is deleted, thereby preventing false detection of the cell voltage. However, the A/D convertor samples the power voltage with a given period and converts the sampled voltage into digital data. For this reason, an instantaneous variation of the power voltage occurring between two adjacent sampling timings cannot be detected, thereby causing false detection of the cell voltage in some cases.

The present invention has been made in view of the above situations. An object of the present invention is to provide a battery voltage detector and a battery voltage detecting method which can reliably prevent false detection of a cell voltage due to an instantaneous variation of a power voltage, thereby increasing reliability of cell voltage detection.

### SUMMARY

To solve the above problem, a battery voltage detector according to one aspect of the present invention includes, but is not limited to: a voltage detection circuit; a voltage processor; and a power voltage. The voltage detection circuit is configured to detect a cell voltage of a battery cell. The voltage processor is configured to perform analog-to-digital conversion on the cell voltage with a predetermined period to collect cell voltage detection data. The power voltage monitoring circuit is configured to determine whether or not an instantaneous variation of an externally-supplied power voltage occurs, and output an instantaneous variation detection signal indicating a result of detection to the voltage processor. If the voltage processor detects based on the instantaneous variation detection signal that the instantaneous variation of the externally-supplied power voltage occurs, the voltage processor is configured to delete the cell voltage detection data that is the newest.

A battery voltage detecting method according to another aspect of the present invention includes, but is not limited to the following processes. A cell voltage of a battery cell is detected. Analog-to-digital conversion is performed on the cell voltage with a predetermined period to collect cell voltage detection data. Whether or not an instantaneous variation of an externally-supplied power voltage occurs is determined. An instantaneous variation detection signal indicating a result of detection is output. If it is detected based on the instantaneous variation detection signal that the instantaneous variation of the externally-supplied power voltage occurs, the cell voltage detection data that is the newest is deleted.

### BRIEF DESCRIPTION OF THE DRAWINGS

The above features and advantages of the present invention will be more apparent from the following description of certain preferred embodiments taken in conjunction with the accompanying drawings, in which:

FIG. 1 schematically illustrates a battery voltage detector 1 according to an embodiment of the present invention;

FIG. 2 is a flowchart illustrating a cell voltage detection process performed by a microcomputer;

FIG. 3A is a timing chart illustrating a method of related art for monitoring an externally-supplied power voltage; and

FIG. 3B is a timing chart illustrating a method of the present embodiment for monitoring the externally-supplied power voltage.

### DETAILED DESCRIPTION OF THE PREFERRED EMBODIMENTS

The present invention will now be described herein with reference to illustrative embodiments. The accompanying drawings explain a battery voltage detector and a battery voltage detecting method in the embodiments. The size, the thickness, and the like of each illustrated portion might be different from those of each portion of an actual battery voltage detector.

Those skilled in the art will recognize that many alternative embodiments can be accomplished using the teachings of the present invention and that the present invention is not limited to the embodiments illustrated herein for explanatory purposes.

Hereinafter, an embodiment of the present invention is explained with reference to the accompanying drawings.

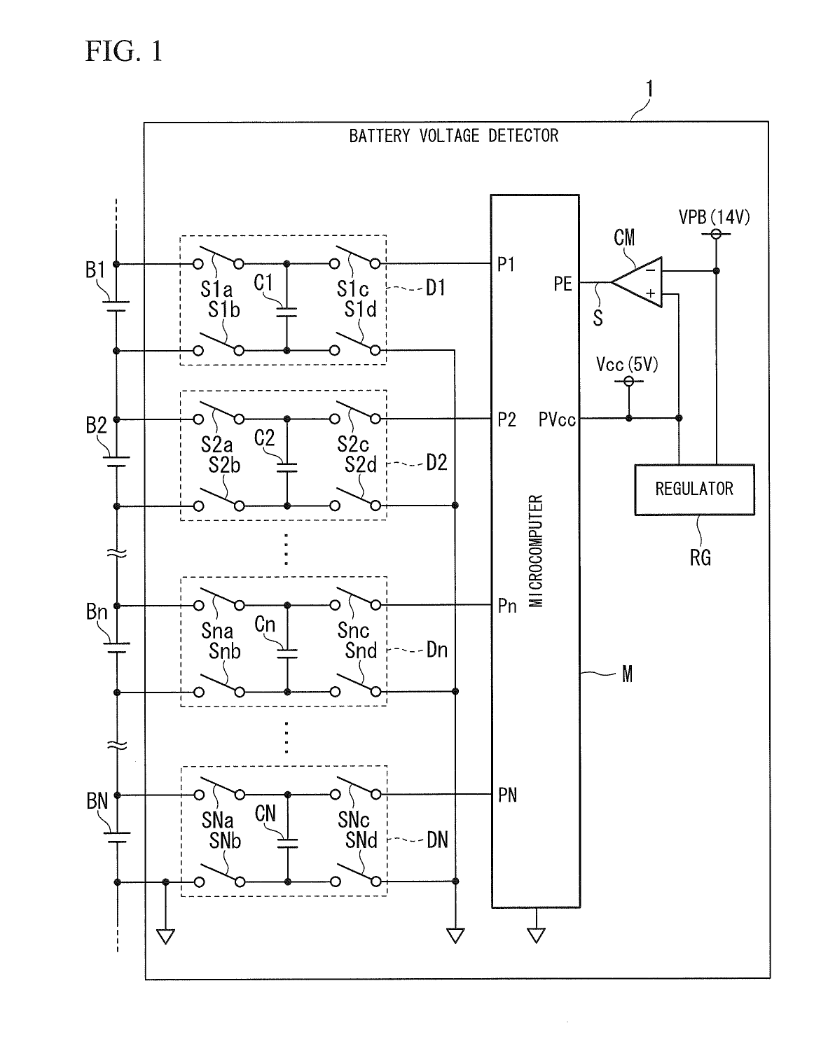

FIG. 1 schematically illustrates a battery voltage controller 1 according to an embodiment of the present invention. As shown in FIG. 1, the battery voltage detector 1 is an ECU (Electronic Control Unit) that detects cell voltages of N battery cells B1 to BN connected in series. The battery voltage detector 1 includes: cell voltage detection circuits D1 to DN provided respectively for the battery cells B1 to BN; a regulator (reference power circuit) RG; a comparator (power voltage monitoring circuit) CM; and a microcomputer (voltage processor) M.

Each of the cell voltage detection circuits D1 to DN has the same circuit configuration. In other words, the n-th cell voltage detection circuit (n is an integer of 1 to N), which is appended with a reference symbol Dn, includes: a flying capacitor Cn; a first input switch Sna; a second input switch Snb; a first output switch Snc; and a second output switch Snd.

The flying capacitor Cn is a capacitor used as a recording medium that temporarily stores a voltage between terminals (cell voltage) of the n-th battery cell Bn. The first input switch Sna, the second input switch Snb, and the first output switch Snc, and the second output switch Snd are switching elements, such as MOSFET (Metal Oxide Semiconductor-Field Effect Transistor), the on/off-state of which are controlled by the microcomputer M.

One terminal of the flying capacitor Cn is connected to a positive electrode terminal of the battery cell Bn via the first input switch Sna, and is connected to the n-th cell voltage input port Pn of the microcomputer M via the first output switch Snc. The other terminal of the flying capacitor Cn is connected to a negative electrode terminal of the battery cell Bn via the second input switch Snb, and is connected to a common potential line (for example, a ground line) in the battery voltage detector 1 via the second output switch Snd. The other cell voltage detection circuits have the same circuit configuration as that of the n-th cell voltage detection circuit Dn (may substitute a different number in n), and therefore explanations thereof are omitted here.

The regulator RG is a power stabilization circuit that decreases an externally-supplied power voltage VPB (for example, 14V) and generates a reference power voltage Vcc (for example, 5V) for operating each electric component in the battery voltage detector 1. The externally-supplied power voltage VPB is obtained by decreasing an output voltage of a motor driving battery (for example, 144V) using a voltage convertor, such as a DC/DC convertor.

The reference power voltage Vcc generated by the regulator RG is supplied to a power voltage input port PVcc of the microcomputer M, and is supplied to a non-inverting input terminal (+terminal) of the comparator CM. Additionally, the externally-supplied power voltage VPB is supplied to an inverting input terminal (−terminal) of the comparator CM.

The comparator CM compares the externally-supplied power voltage VPB input to the inverting input terminal and the reference power voltage Vcc input to the non-inverting input terminal. Thereby, the comparator CM determines whether or not an instantaneous variation of the externally-supplied power voltage VPB occurs, and outputs an instantaneous variation detection signal S indicating a result of the determination to an edge detection port PE of the microcomputer M. Specifically, the comparator CM outputs a low-level instantaneous variation detection signal S if the externally-supplied power voltage VPB is higher than the reference power voltage Vcc. The comparator CM changes the instantaneous variation detection signal S from the low level to a high level if the externally-supplied power voltage VPB is equal to or lower than the reference power voltage Vcc.

The microcomputer M is a microcomputer including a memory such as a ROM, a RAM, or the like, a CPU (Central Processing Unit), an A/D (analog to digital) convertor, an input/output interface, and the like. The microcomputer M has a function of controlling switches of the respective cell voltage detection circuits D1 to DN, and a function of collecting cell voltage detection data by performing, with a given period, A/D conversion on voltages input to the respective cell voltage input ports P1 to PN (i.e., output voltages of the respective cell voltage detection circuits D1 to DN).

As a distinguishing function of the present embodiment, the microcomputer M has a function of deleting the newest cell voltage detection data if the microcomputer M detects that an instantaneous variation of the externally-supplied power voltage VPB occurs, based on the instantaneous variation detection signal S input to the edge detection port PE. Specifically, the microcomputer M includes a latch circuit that latches a level of the instantaneous variation detection signal S in synchronization with a rising edge of the instantaneous variation detection signal S. The microcomputer M obtains an output level of the latch circuit as edge occurrence generation. If the edge occurrence information is “1” or the voltage level of the edge detection port PE is high, the microcomputer M deletes the newest cell voltage detection data.

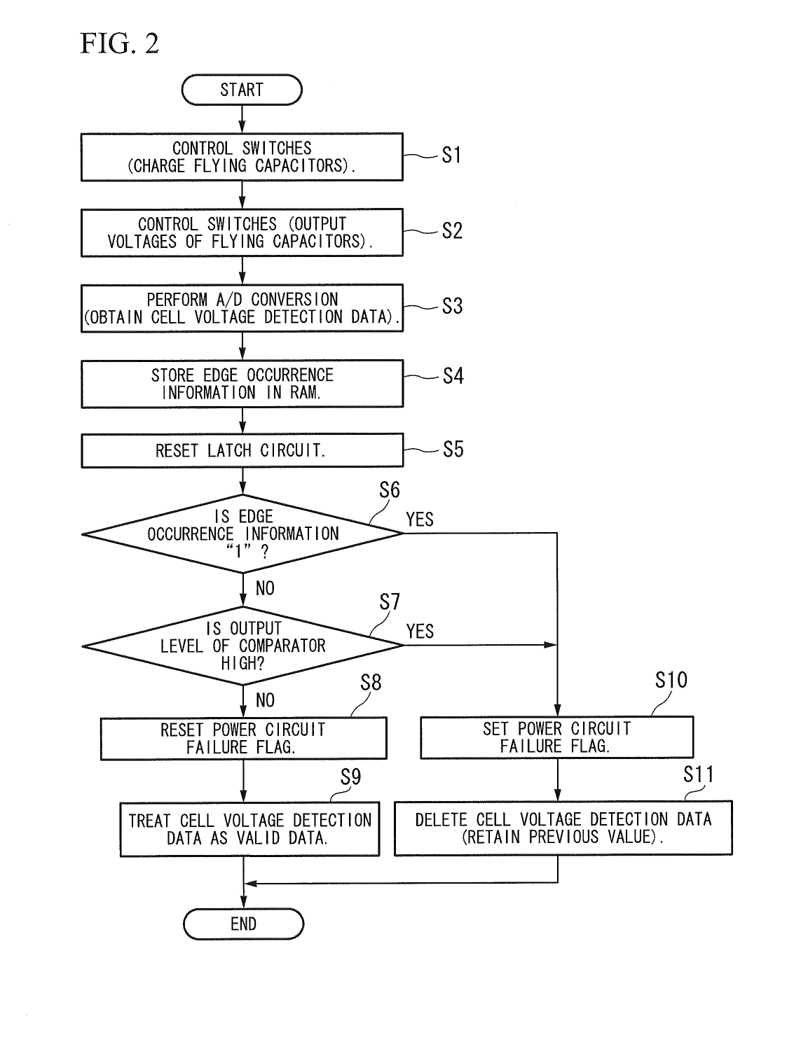

Hereinafter, operation of the battery voltage detector 1 having the aforementioned configuration is explained. FIG. 2 is a flowchart illustrating a cell voltage detection process performed by the microcomputer M. The microcomputer M repeatedly performs the cell voltage detection process shown in FIG. 2 with a given period, thereby collecting cell voltage detection data of the respective battery cells B1 to BN.

As shown in FIG. 2, the microcomputer M first controls the first switches S1a to SNa and the second input switches S1b to SNb of the cell voltage detection circuits D1 to DN to be on-state, and controls the other switches to be off-state (step S1). Thereby, the flying capacitors C1 to CN are charged respectively by the battery cells B1 to BN.

After the charging of the flying capacitors C1 to CN is completed, the microcomputer M controls the first output switches S1c to SNc and the second output switches S1d to SNd of the cell voltage detection circuits D1 to DN to be on-state, and controls the other switches to be off-state (step S2). Thereby, the voltage between the terminals of each of the flying capacitors C1 to CN (corresponding to a cell voltage of each of the battery cells B1 to BN) is input to corresponding one of the cell voltage input ports P1 to PN.

The microcomputer M performs A/D conversion on the input voltages of the cell voltage input ports P1 to PN (i.e., output voltages of the cell voltage detection circuits D 1 to DN) to generate cell voltage detection data. Then, the microcomputer M stores, in an internal memory (for example, a RAM), the cell voltage detection data as current detection values of the cell voltages (step S3). In other words, the cell voltage detection data, which are obtained each time the cell voltage detection process is performed with the given period, are stored in the RAM in a time-oriented manner.

Then, the microcomputer M obtains an output level of the latch circuit as edge occurrence information, and stores the edge occurrence information in the internal memory (for example, a RAM) (step S4). As explained above, the latch circuit is a circuit that latches a level of an instantaneous variation detection signal S in synchronization with a rising edge of the instantaneous variation detection signal S input to the edge detection port PE from the comparator CM. Therefore, if the externally-supplied power voltage VPB is equal to or lower than the reference power voltage Vcc at least one time before the process in step S4 (i.e., if an instantaneous variation occurs), the output level of the latch circuit (edge occurrence information) must have been “1.”

Then, the microcomputer M resets the latch circuit to reset the output level of the latch to “0” (step S5). Then, the microcomputer M determines whether or not the edge occurrence information stored in the RAM is “1,” that is, whether or not an instantaneous variation of the externally-supplied power voltage VPB has occurred in the past (step S6). Here, “in the past” means a time interval from the timing in which the process in step S5 is performed in the previous cell voltage detection process to the timing in which the process in step S4 is performed in the current cell voltage detection process.

If “No” in step S6, the microcomputer M determines whether or not the current voltage level of the edge detection port PE (i.e., the output level of the comparator CM) is high, that is, whether or not an instantaneous variation of the externally-supplied power voltage VPB is occurring at present (step S7).

If “No” in step S7, that is, if it is determined that an instantaneous variation of the externally-supplied power voltage VPB has not occurred neither in the past nor at present, the microcomputer M resets the power circuit failure flag to “0” (step S8). Then, the microcomputer M treats, as valid data, the newest cell voltage detection data (cell voltage detection data obtained in the current cell voltage detection process) stored in the RAM (step S9).

On the other hand, if “YES” in step S6 (i.e., if an instantaneous variation of the externally-supplied power voltage VPB has occurred in the past), or if “YES” in step S7 (i.e., if an instantaneous variation of the externally-supplied power voltage VPB is occurring at present), the microcomputer M sets “1” to the power circuit failure flag (step S10), and deletes the newest cell voltage detection data stored in the RAM (step S11).

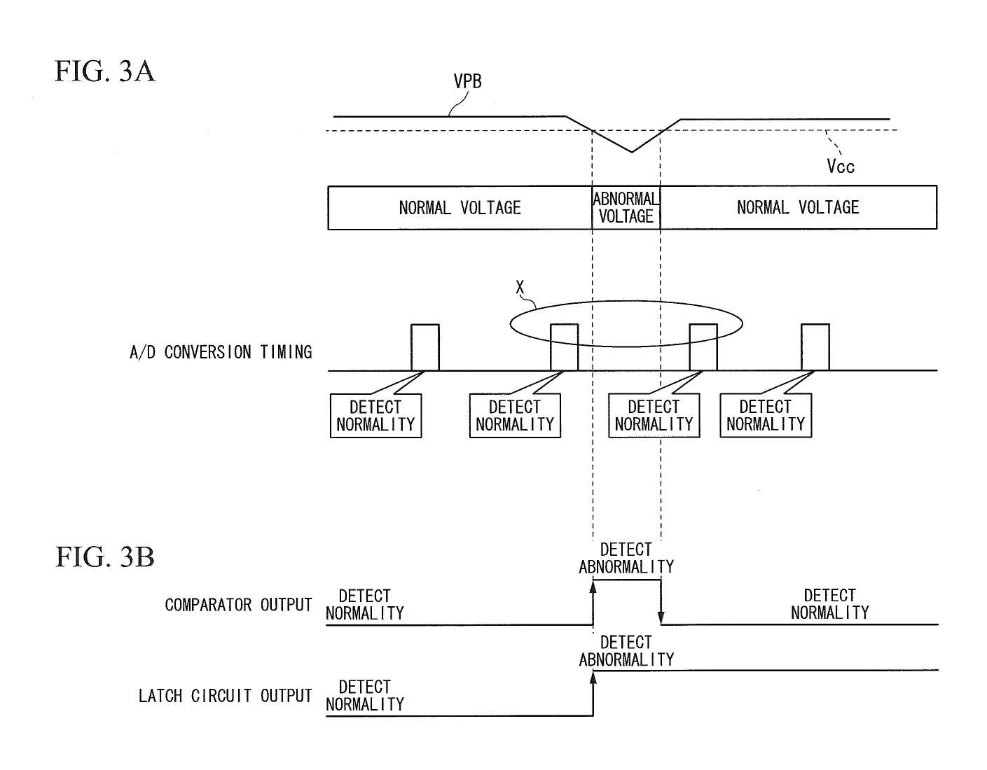

FIG. 3A is a timing chart illustrating a method of the related art for monitoring the externally-supplied power voltage VPB. FIG. 3B is a timing chart illustrating a method of the present embodiment for monitoring the externally-supplied power voltage VPB. Specifically, FIG. 3A illustrates a timing for the A/D convertor to sample the externally-supplied power voltage VPB. FIG. 3B illustrates an output level of the instantaneous variation detection signal S output from the comparator CM and an output level of the latch circuit (edge occurrence information).

As shown in FIG. 3A, an instantaneous variation of the externally-supplied power voltage VPB, which occurs between two adjacent sampling timings (as indicated by a reference symbol X), cannot be detected by the method of the related art. However, the instantaneous variation of the externally-supplied power voltage VPB can be detected by the method of the present embodiment.

In other words, according to the present embodiment, an instantaneous variation of the externally-supplied power voltage VPB can be reliably detected, and the newest cell voltage detection data can be deleted. Accordingly, false detection of the cell voltage due to the instantaneous variation of the externally-supplied power voltage VPB can be reliably prevented, thereby enhancing the reliability of the cell voltage detection.

It is apparent that the present invention is not limited to the above embodiments, and may be modified and changed without departing from the scope and spirit of the invention. For example, the case where the cell voltage detection circuits D1 to DN are provided respectively for the battery cells B1 to BN has been explained in the above embodiment. However, only one cell voltage detection circuit may be provided such that a flying capacitor of the cell voltage detection circuit is connected sequentially to each of the battery cell B1 to BN using a multiplexer or the like, thereby sequentially detecting a cell voltage of each of the battery cells B1 to BN. If the multiplexer is used, the first input switch of the cell voltage detection circuit may be excluded.

What is claimed is:

1. A battery voltage detector comprising:
a voltage detection circuit configured to detect a cell voltage of a battery cell;
a voltage processor configured to perform analog-to-digital conversion on the cell voltage with a predetermined period to collect cell voltage detection data; and
a power voltage monitoring circuit configured to determine whether or not an instantaneous variation of an externally-supplied power voltage occurs, and output an instantaneous variation detection signal indicating a result of detection to the voltage processor,
wherein if the voltage processor detects based on the instantaneous variation detection signal that the instantaneous variation of the externally-supplied power voltage occurs, the voltage processor is configured to delete the cell voltage detection data that is the newest.

2. The battery voltage detector according to claim 1, further comprising:
a reference power circuit configured to decrease the externally-supplied power voltage to generate a reference power voltage,
wherein the power voltage monitoring circuit is configured to compare the externally-supplied power voltage and the reference power voltage to determine whether or not the instantaneous variation of the externally-supplied power voltage occurs.

3. The battery voltage detector according to claim 2, wherein if the externally-supplied power voltage is equal to or lower than the reference power voltage, the power voltage monitoring circuit is configured to output, to the voltage processor, the instantaneous variation detection signal having a level that is inverted, and
the voltage processor is configured to delete the cell voltage detection data that is the newest, when the level of the instantaneous variation detection signal is inverted.

4. A battery voltage detecting method comprising:
detecting a cell voltage of a battery cell;
performing analog-to-digital conversion on the cell voltage with a predetermined period to collect cell voltage detection data;
determining whether or not an instantaneous variation of an externally-supplied power voltage occurs;
outputting an instantaneous variation detection signal indicating a result of detection; and
if it is detected based on the instantaneous variation detection signal that the instantaneous variation of the externally-supplied power voltage occurs, deleting the cell voltage detection data that is the newest.

5. The battery voltage detecting method according to claim 4, further comprising:
decreasing the externally-supplied power voltage to generate a reference power voltage, and
outputting the instantaneous variation detection signal comprising comparing the externally-supplied power voltage and the reference power voltage to determine whether or not the instantaneous variation of the externally-supplied power voltage occurs.

6. The battery voltage detecting method according to claim 5, wherein outputting the instantaneous variation detection signal comprising outputting the instantaneous variation detection signal having a level that is inverted, and
deleting the cell voltage detection data comprising deleting the cell voltage detection data that is the newest when the level of the instantaneous variation detection signal is inverted.
